(19) United States
(12) Patent Application Publication
(10) Pub. No.: US 2023/0204664 A1
(43) Pub. Date: Jun. 29, 2023

(54) WAFER CHIP TESTING METHOD AND APPARATUS, ELECTRONIC DEVICE AND STORAGE MEDIUM

(71) Applicant: Saimeite Technology Co., Ltd., Jiangsu (CN)

(72) Inventors: Gangjiang LI, Jiangsu (CN); Youhui ZHANG, Jiangsu (CN); Song JIN, Jiangsu (CN)

(21) Appl. No.: 17/951,776

(22) Filed: Sep. 23, 2022

(30) Foreign Application Priority Data
Dec. 29, 2021 (CN) 202111642521.3

(51) Int. Cl. G01R 31/3185; G01R 1/04

(52) U.S. Cl. CPC G01R 31/318511; G01R 1/0491

(57) ABSTRACT

A wafer chip testing method and apparatus, an electronic device and a storage medium are provided. The testing method includes: comparing each configuration parameter of each wafer chip with a standard specification threshold interval of a corresponding parameter type, and marking as marked test parameters configuration parameters which do not belong to the standard specification threshold intervals; and inputting all marked test parameters of individual wafer chip into a combination rule judgment function respectively, outputting wafer chip(s) which does not conform to any one or more rules in the combination rule judgment function, and determining the wafer chip(s) as unqualified wafer chip(s).

### CROSS-REFERENCE TO RELATED APPLICATION

This application claims priority to Chinese Patent Application No. 202111642521.3, filed on Dec. 29, 2021, entitled “WAFER CHIP TESTING METHOD AND APPARATUS, ELECTRONIC DEVICE AND STORAGE MEDIUM,” the disclosure of which is hereby incorporated herein in its entirety.

### TECHNICAL FIELD

The present application relates to the field of wafer chip testing technologies, and particularly to a wafer chip testing method and apparatus, an electronic device and a storage medium.

### BACKGROUND ART

In a field of semiconductor technologies, a test of a wafer chip is an important step for judging whether the wafer chip is qualified, and the test of the wafer chip refers to a series of electrical tests of individual parameters of integrated circuits on a plurality of regions on the wafer chip and is used for judging whether the integrated circuits in the wafer chip are defective and whether the wafer chip is qualified. In a prior art, for the test of the wafer chip, a professional technician is required to define and set groups of the parameters using a programming language, determine average values of the grouped parameters by a programming operation, and judge whether the wafer chip is qualified according to the average values, however, judgment standards are required to depend on expertise of the technician, and a calculation is performed only with a programming method, resulting in many iterative calculation processes, low accuracy and inconvenient subsequent adjustment and modification to the wafer chip.

### SUMMARY

In view of this, an object of the present application is to provide a wafer chip testing method and apparatus, an electronic device and a storage medium, in which dual judgment is performed on a wafer chip through a judgment function using parameter types and combination rules, so as to determine whether quality of the wafer chip is qualified, thus improving accuracy of judging whether the quality of the wafer chip is qualified; moreover, an unqualified wafer chip is adjusted and modified using a defective marked test parameter, thereby improving an adjustment and modification efficiency.

Embodiments of the present application provide a wafer chip testing method and apparatus, an electronic device and a storage medium, the testing method including:

acquiring a plurality of configuration parameters of each wafer chip in a target test region in a working process;

inputting all marked test parameters of each wafer chip into a combination rule judgment function, outputting a wafer chip which does not conform to any one or more rules in the combination rule judgment function, and determining the wafer chip as an unqualified wafer chip;

inputting the individual marked test parameter into the combination rule judgment function, outputting a marked test parameter which does not conform to any one or more rules in the combination rule judgment function, and determining a target wafer chip corresponding to the marked test parameter as an unqualified wafer chip; and

processing the individual unqualified wafer chips in different adjustment and modification ways according to the number of the rules in the combination rule judgment function to which the unqualified wafer chips correspond and do not conform.

Further, before the acquiring a plurality of configuration parameters of each wafer chip in a target test region in a working process, the testing method further includes:

determining that a test type of the target test region is matched with a chip type of the wafer chip.

Further, a standard specification threshold interval of a parameter type corresponding to each configuration parameter is acquired by:

determining the parameter type corresponding to each configuration parameter according to a production number of the wafer chip; and

acquiring, from a parameter-type and threshold-interval mapping table, the standard specification threshold interval of the parameter type corresponding to each configuration parameter.

Further, any wafer chip is determined not to conform to a first rule in the combination rule judgment function by the following steps:

dividing each wafer chip into first regions, and determining the number of marked test parameters in each region; and

determining, if the number of the marked test parameters in any region is greater than a first threshold, that the wafer chip does not conform to the first rule in the combination rule judgment function.

Further, any wafer chip is determined not to conform to a second rule in the combination rule judgment function by the following steps:

dividing each wafer chip into second regions, and determining the number of second regions containing marked test parameters;

judging, if the number of the second regions is greater than a second threshold, whether parameter types corresponding to the marked test parameters in each second region are the same; and

determining, if the parameter types corresponding to the marked test parameters in each second region are the same, that the wafer chip does not conform to the second rule in the combination rule judgment function.

Further, any wafer chip is determined not to conform to a third rule in the combination rule judgment function by the following steps:

counting a first number of marked test parameters and a second number of configuration parameters in the wafer chip, respectively; and

determining, if a ratio of the first number to the second number of the wafer chip is greater than a first preset ratio, that the wafer chip does not conform to the third rule in the combination rule judgment function.

Further, any wafer chip is determined not to conform to a fourth rule in the combination rule judgment function by the following steps:

dividing each wafer chip into third regions, and determining the number of third regions containing marked test parameters;

counting a fourth number of marked test parameters in the wafer chip and a third number of the marked test parameters in each third region, respectively; and

determining, if a ratio of the third number of any third region to the fourth number of the wafer chip is greater than a second preset ratio, that the wafer chip does not conform to the fourth rule in the combination rule judgment function.

An embodiment of the present application further provides a wafer chip testing apparatus, including:

an acquiring module configured to acquire a plurality of configuration parameters of each wafer chip in a target test region in a working process;

a marking module configured to compare each configuration parameter of each wafer chip with a standard specification threshold interval of a corresponding parameter type, and mark, as marked test parameter(s), configuration parameter(s) which do not belong to the standard specification threshold interval(s);

a first determining module configured to input all the marked test parameters of each wafer chip into a combination rule judgment function, output a wafer chip which does not conform to any one or more rules in the combination rule judgment function, and determine the wafer chip as an unqualified wafer chip; and

an adjusting and modifying module configured to process the individual unqualified wafer chips in different adjustment and modification ways according to the number of the rules in the combination rule judgment function to which the unqualified wafer chips correspond and do not conform.

An embodiment of the present application further provides an electronic device, including: a processor, a memory and a bus, the memory storing machine-readable instructions executable by the processor, the processor communicating with the memory through the bus when the electronic device runs, and the machine-readable instructions, when executed by the processor, performing the steps of the testing method as described above.

An embodiment of the present application further provides a computer-readable storage medium having a computer program stored thereon, the computer program, when executed by a processor, performing the steps of the testing method as described above.

Compared with the prior art, in the wafer chip testing method and apparatus according to the embodiments of the present application, the marked configuration parameters exceeding the standard specification threshold intervals are first input into the combination rule judgment function, and the target wafer chips corresponding to the marked test parameters which do not conform to any one or more rules in the combination rule judgment function is determined as the unqualified wafer chips; in the present application, the dual judgment is performed on the wafer chip through the judgment function using the parameter types and the combination rules, so as to determine whether the quality of the wafer chip is qualified, thus improving the accuracy of judging whether the quality of the wafer chip is qualified; moreover, the unqualified wafer chips are adjusted and modified using the defective marked test parameters, thereby improving the adjustment and modification efficiency.

In order to make the above mentioned objects, features, and advantages of the present application more apparent and understandable, preferred embodiments are described in detail hereinafter by referring to the accompanying drawings. The detailed description is made as follows.

### BRIEF DESCRIPTION OF DRAWINGS

To describe the technical solutions in the embodiments of the present application more clearly, the following briefly describes the accompanying drawings required to be used in the embodiments. It should be understood that the following accompanying drawings show merely some embodiments of the present application and therefore should not be considered as limiting the scope, and a person of ordinary skill in the art may still derive other related drawings from these accompanying drawings without creative efforts.

FIG. 1 shows a flow chart of a wafer chip testing method according to an embodiment of the present application;

FIG. 2 shows a flow chart of another wafer chip testing method according to an embodiment of the present application;

FIG. 3 shows a schematic structural diagram of a wafer chip testing apparatus according to an embodiment of the present application;

FIG. 4 shows a schematic structural diagram of another wafer chip testing apparatus according to an embodiment of the present application; and

FIG. 5 shows a schematic structural diagram of an electronic device according to an embodiment of the present application.

In the drawings:

300—testing apparatus; 310—second determining module; 320—acquiring module; 330—marking module; 340—first determining module; 350—adjusting and modifying module; 500—electronic device; 510—processor; 520—memory; 530—bus.

### DETAILED DESCRIPTION

To make the objectives, technical solutions and advantages of the embodiments of the present application clearer, the technical solutions in the embodiments of the present application are clearly and completely described with reference to the accompanying drawings in the embodiments of the present application, and apparently, the described embodiments are not all but only some of the embodiments of the present application. Generally, the components of the embodiments of the present application described and illustrated in the drawings herein may be arranged and designed in a variety of different configurations. Accordingly, the following detailed description of the embodiments of the present application provided in the drawings is not intended to limit the scope of protection of the present application, but only represents selected embodiments of the present application. All other embodiments obtained by those skilled in the art based on the embodiments of the present application without creative efforts shall fall within the protection scope of the present application.

First, an application scenario to which the present application is applicable will be described. It is found after researches that in a field of semiconductor technologies, a test of a wafer chip is an important step for judging whether the wafer chip is qualified, and the test of the wafer chip refers to a series of electrical tests of individual parameters of integrated circuits on a plurality of regions on the wafer chip and is used for judging whether the integrated circuits in the wafer chip are defective and whether the wafer chip is qualified. In the prior art, for the test of the wafer chip, a professional technician is required to define and set groups of the parameters using a programming language, determine average values of the grouped parameters by a programming operation, and judge whether the wafer chip is qualified according to the average values, however, judgment standards are required to depend on expertise of the technician, and a calculation is performed only with a programming method, resulting in many iterative calculation processes, low accuracy and inconvenient subsequent adjustment and modification to the wafer chip.

Based on this, embodiments of the present application provide a wafer chip testing method and apparatus, an electronic device and a storage medium, wherein marked configuration parameters exceeding standard specification threshold intervals are first input into a combination rule judgment function, and a target wafer chip corresponding to a marked test parameter which does not conform to any one or more rules in the combination rule judgment function is determined as an unqualified wafer chip; in the present application, dual judgment is performed on a wafer chip through the judgment function using parameter types and combination rules, so as to determine whether quality of the wafer chip is qualified, thus improving accuracy of judging whether the quality of the wafer chip is qualified; moreover, the unqualified wafer chip is adjusted and modified using a defective marked test parameter, thereby improving an adjustment and modification efficiency, avoiding the process of determining the average values of the parameters by the programming operation dependent on the technician with high expertise in the traditional parameter testing process in the prior art, and reducing a large number of iterative calculations in the traditional programming process; and judgment is performed using the combination rules, thus improving the accuracy.

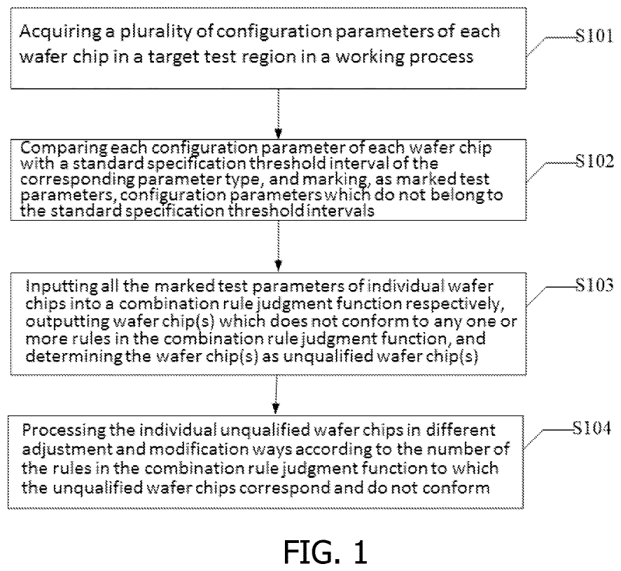

Reference is made to FIG. 1 which is a flow chart of a wafer chip testing method according to an embodiment of the present application. As shown in FIG. 1, the testing method according to the embodiment of the present application includes:

S101: acquiring a plurality of configuration parameters of each wafer chip in a target test region in a working process.

In this step, during a test of each wafer chip in the target test region in the working process, it is necessary to judge whether each wafer chip is a qualified wafer chip, and at this point, the plurality of configuration parameters of each wafer chip in the target test region are required to be acquired first, and the configuration parameters include, but are not limited to, individual electrical parameters of an integrated circuit on the wafer chip, a resistivity of the chip, and a thickness of the wafer chip.

Here, after produced and before leaving a factory, the wafer chips are subjected to the above-mentioned test in the working process, i.e., an electrical test, which is called a wafer acceptance test (WAT), and after the WAT is completed, some unqualified wafer chips with defective configuration parameters are screened out.

In the above, each configuration parameter corresponds to a parameter type related to the configuration parameter and a chip type corresponding to the parameter type.

S102: comparing each configuration parameter of each wafer chip with a standard specification threshold interval of the corresponding parameter type, and marking, as marked test parameters, configuration parameters which do not belong to the standard specification threshold intervals.

In this step, after the plurality of configuration parameters of each wafer chip in the working process are obtained, each configuration parameter of each wafer chip is compared with the standard specification threshold interval, and the configuration parameters exceeding or less than the corresponding standard specification threshold intervals are marked as the marked test parameters.

In the above, the standard specification threshold interval of the parameter type corresponding to each configuration parameter is acquired by the following manner:

determining the parameter type corresponding to each configuration parameter according to a production number of the wafer chip.

Here, a corresponding and unique production number is configured for each wafer chip during design and production, and used for a recording purpose and distinction from other wafer chips, so as to facilitate subsequent query work of an operator, and after the production number of each wafer chip is determined, the plurality of parameter types corresponding to the plurality of configuration parameters in each wafer chip may be determined.

The standard specification threshold interval of the parameter type corresponding to each configuration parameter is acquired from a parameter-type and threshold-interval mapping table.

Here, in the parameter-type and threshold-interval mapping table, the parameter type corresponding to each configuration parameter is mapped to one standard specification threshold interval, and the standard specification threshold interval corresponding to the parameter type may be determined according to the type of each configuration parameter.

S103: inputting all the marked test parameters of individual wafer chips into a combination rule judgment function respectively, outputting wafer chip(s) which does not conform to any one or more rules in the combination rule judgment function, and determining the wafer chip(s) as unqualified wafer chip(s).

In this step, the obtained marked test parameters of the target test region are input into the combination rule judgment function, the wafer chip corresponding to the marked test parameter which does not conform to any rule in a combination or combination rules is determined according to any one or more rules in the combination rule judgment function, and the target wafer chip is determined as the unqualified wafer chip.

Thus, the combination rule judgment function is a judgment function composed of a plurality of rules, and the number and setting conditions of the combination rules may be set in a self-defining way according to requirements; and the judgment function includes, but is not limited to, an Oracle SQL function.

In the above, the Oracle SQL function is used for representing a special function for executing a specific operation, and the special function may greatly enhance functions of a “SQL” language. Here, two types of functions are mainly used for “oracle” as a database: a single-row function and an aggregation function, and the Oracle SQL function is mainly used for outputting wafer chips which conform to the combination rules.

In the above description, after the wafer chip is determined as the unqualified wafer chip, alarm information is sent to an external management platform or a third-party mobile terminal, and the operator is reminded to subsequently adjust and modify the unqualified wafer chip.

Here, in the embodiment of the present application, four rules are set for each wafer chip according to test requirements.

Further, any wafer chip is determined not to conform to a first rule in the combination rule judgment function by the following step:

dividing each wafer chip into first regions, and determining the number of marked test parameters in each region.

Here, for each wafer chip, each wafer chip is divided according to the first region, and the number of the marked test parameters in each region and the number of the configuration parameters corresponding to the marked test parameters in each region are determined.

If the number of the marked test parameters in any region is greater than a first threshold, the wafer chip is determined not to conform to the first rule in the combination rule judgment function.

Here, if the number of the marked test parameters in any first region is greater than the first threshold, it indicates that the marked test parameters of this region of the chip include many defective parameters, and therefore, the chip is defective and does not conform to the first rule in the combination rule judgment function; and if the chip does not conform to the first rule in the combination rule judgment function, all the wafer chips which do not conform to the first rule are output and determined as the unqualified wafer chips.

Further, any wafer chip is determined not to conform to a second rule in the combination rule judgment function by the following step:

dividing each wafer chip into second regions, and determining the number of second regions containing marked test parameters.

Here, after each wafer chip is subjected to second region division, different from the result determined according to the dividing manner of the first region, at this point, the number of the second regions containing the marked test parameters in the wafer chip is required to be determined.

If the number of the second regions is greater than a second threshold, whether parameter types corresponding to the marked test parameters in each second region are the same is judged.

Here, on the basis that the number of the second regions containing the marked test parameters in the wafer chip is greater than the second threshold, the parameter types corresponding to the marked test parameters in each second region are determined, and whether the individual parameter types are the same is judged, the sameness here including that at least one parameter type in each second region is same.

Thus, the second threshold is a ratio of the number of the corresponding regions containing the marked test parameters in the wafer chip to a number of the second regions.

If the parameter types corresponding to the marked test parameters in each second region are the same, the wafer chip is determined not to conform to the second rule in the combination rule judgment function.

Here, if at least one of the parameter types is same in the individual parameter types corresponding to the marked test parameters in any second region, it indicates that the marked test parameters corresponding to the same parameter type in different second regions of the wafer chip have many defective parameters, and therefore, the wafer chip is defective and does not conform to the second rule in the combination rule judgment function; and if the wafer chip does not conform to the second rule in the combination rule judgment function, the wafer chips which do not conform to the second rule are output and determined as the unqualified wafer chips.

Further, any wafer chip is determined not to conform to a third rule in the combination rule judgment function by the following step:

counting a first number of marked test parameters and a second number of configuration parameters in the wafer chip respectively.

Here, the first number is used to characterize the marked test parameters in the wafer chip, and the second number is used to characterize all the configuration parameters in the wafer chip.

If a ratio of the first number to the second number of the wafer chip is greater than a first preset ratio, the wafer chip is determined not to conform to the third rule in the combination rule judgment function.

In the above description, assuming that the first preset ratio is 10%, each wafer chip is divided into 5 regions, and each region corresponds to 10 parameter types, the number of the configuration parameters of the wafer chips in this batch is 50, and if the number of the marked test parameters of the wafer chip is greater than 5, the wafer chip is determined not to conform to the third rule in the combination rule judgment function.

In the above, wafer chips of a certain batch may also be divided according to the third rule, and since different batches of wafer chips may have different chip types or processing technologies, quality control regulations and dimensions may be different.

The following specific steps are performed when the chips of a certain batch are divided using the third rule.

First batch division is performed on the wafer chips, and the number of marked test parameters in each batch of wafer chips is determined.

If a ratio of the number of the marked test parameters in any batch of wafer chips to a number of configuration parameters of this batch of wafer chips is greater than a preset ratio, the batch of wafer chips is determined not to conform to the third rule in the combination rule judgment function.

Here, assuming that the first preset ratio is 10%, the number of the wafer chips in any batch is 25, each wafer chip is divided into 5 target regions, and each target region corresponds to 10 parameter types, the number of the configuration parameters of this batch of wafer chips is 1250, and if the number of the marked test parameters of this batch of wafer chips is greater than 125, this batch of wafer chips is determined not to conform to the third rule in the combination rule judgment function.

Thus, if the chips do not conform to the third rule in the combination rule judgment function, all the wafer chips which do not conform to the third rule in the combination rule judgment function are output and determined as the unqualified wafer chips.

Further, any wafer chip is determined not to conform to a fourth rule in the combination rule judgment function by the following steps:

dividing each wafer chip into third regions, and determining the number of third regions containing marked test parameters.

Here, by dividing each wafer chip into the third regions, the number of the third regions containing the marked test parameters in each wafer chip is determined, so as to perform the judgment of the fourth rule.

A fourth number of marked test parameters in the wafer chip and a third number of the marked test parameters in each third region are counted respectively.

Here, the third number is used to characterize the number of the marked test parameters in each third region in each wafer chip.

If a ratio of the third number of any third region to the fourth number of the wafer chip is greater than a second preset ratio, the wafer chip is determined not to conform to the fourth rule in the combination rule judgment function.

Here, assuming that the second preset ratio is 25%, and each wafer chip is divided into 5 third regions, if the fourth number of the marked test parameters of the wafer chip is 40, when the number of the marked test parameters in one third region exceeds 10, the wafer chip is determined not to conform to the fourth rule in the combination rule judgment function.

In the above, whether different batches of wafer chips are qualified may be judged according to a set new batch rule, and since different batches of wafer chips may have different chip types or processing technologies, quality control regulations and dimensions may be different.

The following specific steps are performed when whether the quality of a certain batch of chips is qualified is judged using the new batch rule.

Second batch division is performed on the wafer chips, and the number of marked test parameters in each batch of wafer chips is determined.

If the marked test parameters corresponding to at least one same parameter type exist in the same regions in a preset number of wafer chips in each batch of wafer chips, all the wafer chips in this batch are unqualified wafer chips.

Here, assuming that the number of the wafer chips in any batch is 12, when certain regions of more than 25% (3 wafer chips) of the wafer chips are assumed to have the marked test parameters corresponding to one same parameter type, all the wafer chips in the batch are determined as the unqualified wafer chips.

After all the marked test parameters of individual wafer chips are respectively input into the combination rule judgment function for judgment, the number of rules violated in the unqualified wafer chips and the marked test parameters violating any rule are stored externally, thus facilitating a subsequent tracing of the operator.

S104: processing the individual unqualified wafer chips in different adjustment and modification ways according to the number of the rules in the combination rule judgment function to which the unqualified wafer chips correspond and do not conform.

In this step, after the target wafer chips corresponding to the marked test parameters are determined as the unqualified wafer chips, whether the individual unqualified wafer chips are adjusted and modified is determined according to the number of the rules in the combination rule judgment function to which the unqualified wafer chips correspond and do not conform.

Thus, if the unqualified wafer chips do not conform to only part of the rules in the combination rule judgment function, each unqualified wafer chip is adjusted and modified with a corresponding adjustment and modification method according to conditions meeting the rules; and if the unqualified wafer chips do not conform to all the rules in the combination rule judgment function, the wafer chips are directly discarded without adjustment and modification.

Compared with the prior art, in the testing method according to the embodiment of the present application, the dual judgment is performed on the wafer chip through the judgment function using the parameter type and the combination rules, so as to determine whether the quality of the wafer chip is qualified, thus improving the accuracy of judging whether the quality of the wafer chip is qualified; moreover, in the application, the unqualified wafer chips are adjusted and modified using the defective marked test parameters, thereby improving the adjustment and modification efficiency, avoiding the process of determining the average values of the parameters by the programming operation dependent on the technician with high expertise in the traditional parameter testing process in the prior art, and reducing the large number of iterative calculations in the traditional programming process; and judgment is performed using the combination rules, thus improving the accuracy.

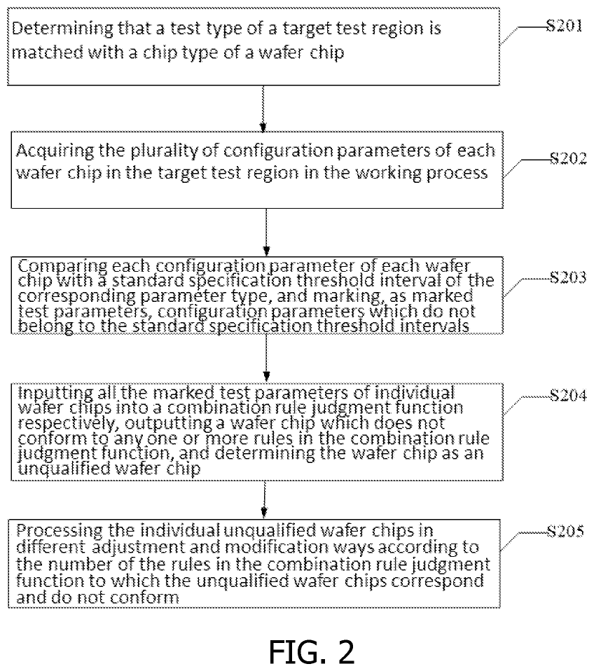

Reference is made to FIG. 2 which is a flow chart of a wafer chip testing method according to another embodiment of the present application. As shown in FIG. 2, the testing method according to the embodiment of the present application includes:

S201: determining that a test type of a target test region is matched with a chip type of a wafer chip.

In this step, before acquisition of a plurality of configuration parameters of each wafer chip in the target test region in a working process, the detectable test type of the target test region for each wafer chip and the chip type of each wafer chip in actual detection are required to be determined, whether the test type of the target test region is matched with the chip type of the wafer chip is judged, and the plural configuration parameters of each wafer chip in the target test region in the working process are acquired under a condition that the test type of the target test region is matched with the chip type of the wafer chip.

S202: acquiring the plurality of configuration parameters of each wafer chip in the target test region in the working process.

S203: comparing each configuration parameter of each wafer chip with a standard specification threshold interval of the corresponding parameter type, and marking, as marked test parameters, configuration parameters which do not belong to the standard specification threshold intervals.

S204: inputting all the marked test parameters of individual wafer chips into a combination rule judgment function respectively, outputting a wafer chip which does not conform to any one or more rules in the combination rule judgment function, and determining the wafer chip as an unqualified wafer chip.

S205: processing the individual unqualified wafer chips in different adjustment and modification ways according to the number of the rules in the combination rule judgment function to which the unqualified wafer chips correspond and do not conform.

In the above, for descriptions of S202 to S205, reference may be made to the descriptions of S101 to S104, same technical effects may be achieved, and details are not repeated.

Compared with the prior art, in the testing method according to the embodiment of the present application, the dual judgment is performed on the wafer chip through the judgment function using the parameter type and the combination rules, so as to determine whether the quality of the wafer chip is qualified, thus improving the accuracy of judging whether the quality of the wafer chip is qualified; moreover, in the present application, the unqualified wafer chips are adjusted and modified using the defective marked test parameters, thereby improving the adjustment and modification efficiency, avoiding the process of determining the average values of the parameters by the programming operation dependent on the technician with high expertise in the traditional parameter testing process in the prior art, and reducing the large number of iterative calculations in the traditional programming process; and judgment is performed using the combination rules, thus improving the accuracy.

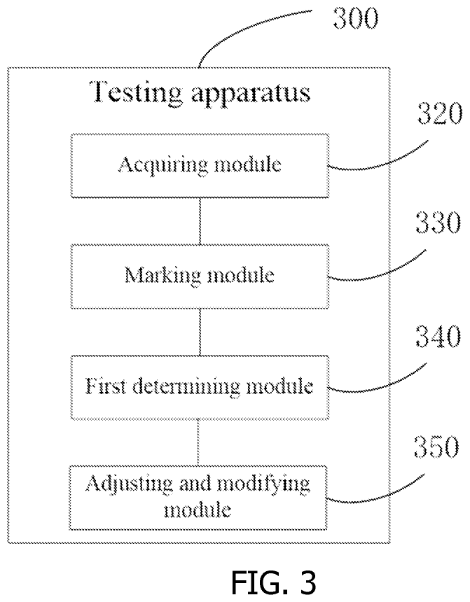

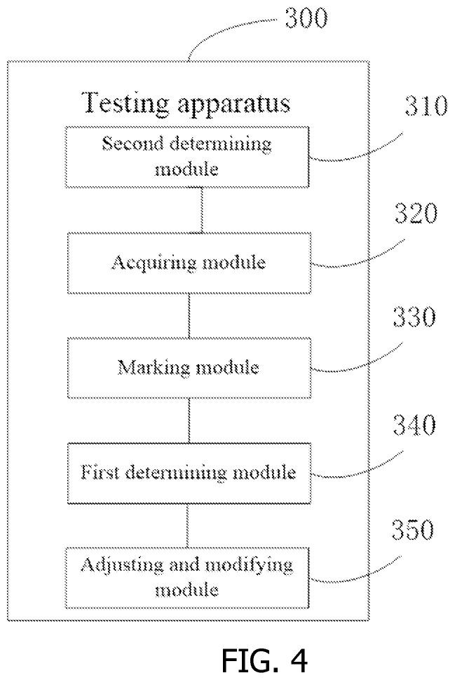

Reference is made to FIG. 3 which is a schematic structural diagram of a wafer chip testing apparatus according to an embodiment of the present application and FIG. 4 which is a schematic structural diagram of another wafer chip testing apparatus according to an embodiment of the present application. As shown in FIG. 3, the testing apparatus 300 includes:

an acquiring module 320 configured to acquire a plurality of configuration parameters of each wafer chip in a target test region in a working process;

a marking module 330 configured to compare each configuration parameter of each wafer chip with a standard specification threshold interval of a corresponding parameter type, and mark as marked test parameters configuration parameters which do not belong to the standard specification threshold intervals;

a first determining module 340 configured to input all the marked test parameters of individual wafer chips into a combination rule judgment function respectively, output wafer chip(s) which does not conform to any one or more rules in the combination rule judgment function, and determine the wafer chip(s) as an unqualified wafer chip(s); and

an adjusting and modifying module 350 configured to process the unqualified wafer chip(s) in different adjustment and modification ways according to the number of the rules in the combination rule judgment function to which the unqualified wafer chip(s) correspond and do not conform.

Compared with the prior art, in the testing apparatus according to the embodiment of the present application, the dual judgment is performed on the wafer chip through the judgment function using the parameter type and the combination rules, so as to determine whether the quality of the wafer chip is qualified, thus improving the accuracy of judging whether the quality of the wafer chip is qualified; moreover, the unqualified wafer chip is adjusted and modified using the defective marked test parameter, thereby improving the adjustment and modification efficiency, avoiding the process of determining the average values of the parameters by the programming operation dependent on the technician with high expertise in the traditional parameter testing process in the prior art, and reducing the large number of iterative calculations in the traditional programming process; judgment is performed using the combination rules, thus improving the accuracy.

Further, as shown in FIG. 4, the testing apparatus 400 includes:

a second determining module 310 configured to determine that a test type of a target test region is matched with a chip type of a wafer chip;

an acquiring module 320 configured to acquire a plurality of configuration parameters of each wafer chip in the target test region in a working process;

a marking module 330 configured to input all the marked test parameters of individual wafer chips into a combination rule judgment function respectively, output a wafer chip which does not conform to any one or more rules in the combination rule judgment function, and determine the wafer chip as an unqualified wafer chip;

a first determining module 340 configured to input each marked test parameter into the combination rule judgment function, output a marked test parameter which does not conform to any one or more rules in the combination rule judgment function, and determine a target wafer chip corresponding to the marked test parameter as an unqualified wafer chip; and

an adjusting and modifying module 350 configured to process the individual unqualified wafer chips in different adjustment and modification ways according to the number of the rules in the combination rule judgment function to which the unqualified wafer chips correspond and do not conform.

Compared with the prior art, in the testing apparatus according to the embodiment of the present application, the dual judgment is performed on the wafer chip through the judgment function using the parameter types and the combination rules, so as to determine whether the quality of the wafer chip is qualified, thus improving the accuracy of judging whether the quality of the wafer chip is qualified; moreover, in the application, the unqualified wafer chips are adjusted and modified using the defective marked test parameters, thereby improving the adjustment and modification efficiency, avoiding the process of determining the average values of the parameters by the programming operation dependent on the technician with high expertise in the traditional parameter testing process in the prior art, and reducing the large number of iterative calculations in the traditional programming process; and judgment is performed using the combination rules, thus improving the accuracy.

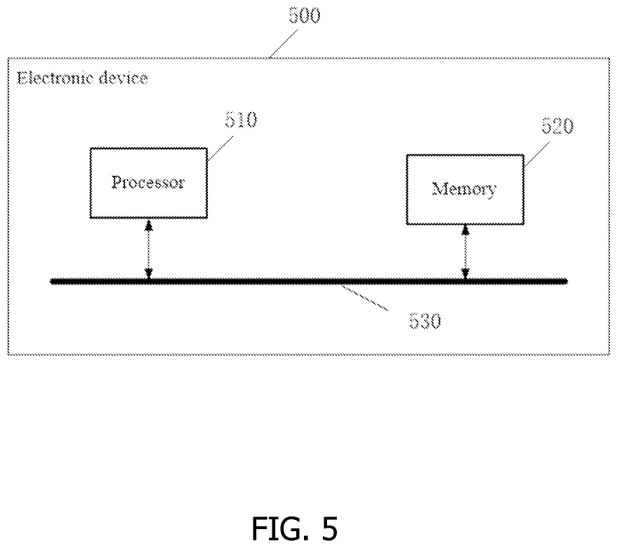

Reference is made to FIG. 5 which is a schematic structural diagram of an electronic device according to an embodiment of the present application. As shown in FIG. 5, the electronic device 500 includes a processor 510, a memory 520 and a bus 530.

The memory 520 stores machine-readable instructions executable by the processor 510, the processor 510 communicates with the memory 520 through the bus 530 when the electronic device 500 runs, the machine-readable instructions, when executed by the processor 510, may execute the steps of the testing methods according to the method embodiments shown in FIGS. 1 and 2, and for specific implementations, reference may be made to the method embodiments, which are not repeated herein.

An embodiment of the present application further provides a computer-readable storage medium having a computer program stored thereon, and the computer program, when executed by a processor, may perform the steps of the testing methods according to the method embodiments shown in FIGS. 1 and 2, and for specific implementations, reference may be made to the method embodiments, which are not repeated herein.

It may be clearly understood by persons skilled in the art that, for the purpose of convenient and brief description, for a detailed working process of the foregoing system, apparatus, and unit, reference may be made to a corresponding process in the foregoing method embodiments, and details are not repeated herein.

In several embodiments provided in the present application, it should be understood that the disclosed system, apparatus, and method may be implemented in other manners. The described apparatus embodiment is only exemplary. For example, the unit division is only logical function division and may be other division in actual implementation. For another example, a plurality of units or components may be combined or integrated into another system, or some features may be ignored or not performed. In addition, the displayed or discussed mutual couplings or direct couplings or communication connections may be implemented through some communication interfaces. The indirect couplings or communication connections between the apparatuses or units may be implemented in electric, mechanical or other forms.

The units described as separate parts may or may not be physically separated, and parts displayed as units may or may not be physical units, may be located in one place, or may be distributed on a plurality of network units. A part or all of the units may be selected according to an actual need to achieve the objectives of the solutions in the embodiments.

In addition, functional units in the embodiments of the present application may be integrated into one processing unit, or each of the units may exist alone physically, or two or more units are integrated into one unit.

When the functional unit is implemented in the form of a software functional unit and sold or used as an independent product, the functional unit may be stored in a non-volatile computer-readable storage medium executable by a processor. Based on such an understanding, the technical solutions of the present application essentially, or the part contributing to the prior art, or a part of the technical solutions may be implemented in the form of a software product. The computer software product is stored in a storage medium and includes several instructions for causing a computer device (which may be a personal computer, a server, or a network device) to perform all or a part of steps of the methods described in the embodiments of the present application. The foregoing storage medium includes: various media that may store program codes, such as a universal serial bus (USB) flash disk, a removable hard disk, a read-only memory (ROM), a random access memory (RAM), a magnetic disk, or an optical disk.

Finally, it should be noted that the above embodiments are only specific implementations of the present application and used to illustrate the technical solutions of the present application, but not to limit them, and the protection scope of the present application is not limited thereto; although the present application is described in detail with reference to the above embodiments, those having ordinary skill in the art should understand that any person skilled in the art still can modify technical solutions recited in the aforesaid embodiments or easily envisage changes or equivalently replace partial technical features therein within the technical scope of the present application; these modifications, changes or substitutions do not make essence of corresponding technical solutions depart from the spirit and scope of the technical solutions of the embodiments of the present application, and are intended to be covered by the protection scope of the present application. Therefore, the protection scope of the present application shall be subject to the protection scope of the claims.

What is claimed is:

1. A wafer chip testing method, comprising:
acquiring a plurality of configuration parameters of each wafer chip in a target test region in a working process;
comparing each configuration parameter of each wafer chip with a standard specification threshold interval of a corresponding parameter type, and marking, as marked test parameters, configuration parameters which do not belong to the standard specification threshold intervals;
inputting all marked test parameters of individual wafer chips into a combination rule judgment function respectively, outputting at least one wafer chip which does not conform to any one or more rules in the combination rule judgment function, and determining the at least one wafer chip as at least one unqualified wafer chip; and
processing the at least one unqualified wafer chip in different adjustment and modification ways according to a number of the rules in the combination rule judgment function to which the at least one unqualified wafer chip corresponds and does not conform.

2. The testing method according to claim 1, wherein before the acquiring a plurality of configuration parameters of each wafer chip in a target test region in a working process, the testing method further comprises:
determining that a test type of the target test region is matched with a chip type of the wafer chip.

3. The testing method according to claim 1, wherein the standard specification threshold interval of the parameter type corresponding to each configuration parameter is acquired by:
determining the parameter type corresponding to each configuration parameter according to a production number of the wafer chip; and
acquiring the standard specification threshold interval of the parameter type corresponding to each configuration parameter from a parameter-type and threshold-interval mapping table.

4. The testing method according to claim 1, wherein any wafer chip is determined not to conform to a first rule in the combination rule judgment function by following steps:
dividing each wafer chip into first regions, and determining a number of marked test parameters in each region; and
determining, if the number of the marked test parameters in any region is greater than a first threshold, that the wafer chip does not conform to the first rule in the combination rule judgment function.

5. The testing method according to claim 1, wherein any wafer chip is determined not to conform to a second rule in the combination rule judgment function by following steps:
dividing each wafer chip into second regions, and determining a number of second regions containing marked test parameters;
judging, if the number of the second regions is greater than a second threshold, whether parameter types corresponding to the marked test parameters in each second region are same; and
determining, if the parameter types corresponding to the marked test parameters in each second region are same, that the wafer chip does not conform to the second rule in the combination rule judgment function.

6. The testing method according to claim 1, wherein any wafer chip is determined not to conform to a third rule in the combination rule judgment function by following steps:
counting a first number of marked test parameters and a second number of configuration parameters in the wafer chip; and
determining, if a ratio of the first number to the second number of the wafer chip is greater than a first preset ratio, that the wafer chip does not conform to the third rule in the combination rule judgment function.

7. The testing method according to claim 1, wherein any wafer chip is determined not to conform to a fourth rule in the combination rule judgment function by following steps:
dividing each wafer chip into third regions, and determining a number of third regions containing marked test parameters;
counting a fourth number of marked test parameters in the wafer chip and a third number of the marked test parameters in each third region; and
determining, if a ratio of the third number of any third region to the fourth number of the wafer chip is greater than a second preset ratio, that the wafer chip does not conform to the fourth rule in the combination rule judgment function.

8. A wafer chip testing apparatus, comprising:
an acquiring module configured to acquire a plurality of configuration parameters of each wafer chip in a target test region in a working process;
a marking module configured to compare each configuration parameter of each wafer chip with a standard specification threshold interval of a corresponding parameter type, and mark, as marked test parameters, configuration parameters which do not belong to the standard specification threshold intervals;
a first determining module configured to input all marked test parameters of individual wafer chip into a combination rule judgment function respectively, output at least one wafer chip which does not conform to any one or more rules in the combination rule judgment function, and determine the at least one wafer chip as at least one unqualified wafer chip; and
an adjusting and modifying module configured to process the at least one unqualified wafer chip in different adjustment and modification ways according to a number of the rules in the combination rule judgment function to which the at least one unqualified wafer chip corresponds and does not conform.

9. An electronic device, comprising: a processor, a memory and a bus, the memory storing machine-readable instructions executable by the processor, the processor communicating with the memory through the bus when the electronic device runs, and the machine-readable instructions, when executed by the processor, performing the steps of the testing method according to claim 1.

10. The electronic device according to claim 9, wherein before the acquiring a plurality of configuration parameters of each wafer chip in a target test region in a working process, the testing method further comprises:
determining that a test type of the target test region is matched with a chip type of the wafer chip.

11. The electronic device according to claim 9, wherein the standard specification threshold interval of the parameter type corresponding to each configuration parameter is acquired by:
determining the parameter type corresponding to each configuration parameter according to a production number of the wafer chip; and
acquiring the standard specification threshold interval of the parameter type corresponding to each configuration parameter from a parameter-type and threshold-interval mapping table.

12. The electronic device according to claim 9, wherein any wafer chip is determined not to conform to a first rule in the combination rule judgment function by following steps:
dividing each wafer chip into first regions, and determining a number of marked test parameters in each region; and
determining, if the number of the marked test parameters in any region is greater than a first threshold, that the wafer chip does not conform to the first rule in the combination rule judgment function.

13. The electronic device according to claim 9, wherein any wafer chip is determined not to conform to a second rule in the combination rule judgment function by following steps:
dividing each wafer chip into second regions, and determining a number of second regions containing marked test parameters;
judging, if the number of the second regions is greater than a second threshold, whether parameter types corresponding to the marked test parameters in each second region are same; and
determining, if the parameter types corresponding to the marked test parameters in each second region are same, that the wafer chip does not conform to the second rule in the combination rule judgment function.

14. The electronic device according to claim 9, wherein any wafer chip is determined not to conform to a third rule in the combination rule judgment function by following steps:
counting a first number of marked test parameters and a second number of configuration parameters in the wafer chip; and
determining, if a ratio of the first number to the second number of the wafer chip is greater than a first preset ratio, that the wafer chip does not conform to the third rule in the combination rule judgment function.

15. The electronic device according to claim 9, wherein any wafer chip is determined not to conform to a fourth rule in the combination rule judgment function by following steps:
dividing each wafer chip into third regions, and determining a number of third regions containing marked test parameters;
counting a fourth number of marked test parameters in the wafer chip and a third number of the marked test parameters in each third region; and
determining, if a ratio of the third number of any third region to the fourth number of the wafer chip is greater than a second preset ratio, that the wafer chip does not conform to the fourth rule in the combination rule judgment function.
